(19) United States
(12) Patent Application Publication
(10) Pub. No.: US 2026/0087225 A1
(43) Pub. Date: Mar. 26, 2026

(54) INVERSE LITHOGRAPHY FOR HIGH QUALITY CURVY MASK GENERATION

(71) Applicant: NVIDIA Corp., Santa Clara, CA (US)

(72) Inventors: Haoyu Yang, Round Rock, TX (US); Haoxing Ren, Austin, TX (US)

(73) Assignee: NVIDIA Corp., Santa Clara, CA (US)

(21) Appl. No.: 19/181,113

(22) Filed: Apr. 16, 2025

Related U.S. Application Data
(60) Provisional application No. 63/699,597, filed on Sep. 26, 2024.

(51) Int. Cl. G06F 30/392; G03F 7/00; G06F 30/398

(52) U.S. Cl. CPC G06F 30/392; G03F 7/706839; G06F 30/398

(57) ABSTRACT

Lithograph mask generation processes that apply optical lithography simulation on a mask image to generate a resist image, perform curvilinear design retargeting on the resist image, determine a gradient from the generated resist image and a configured target resist image, and apply morphological operators and the gradient to update the mask image.

### CROSS-REFERENCE TO RELATED APPLICATIONS

This application claims priority and benefit under 35 U.S.C. 119(e) to U.S. Application Ser. No. 63/699,597, “GPU-Accelerated Inverse Lithography Towards High Quality Curvy Mask Generation”, filed on Sep. 26, 2024, the contents of which are incorporated herein by reference in their entirety.

### BACKGROUND

Inverse Lithography Technology (ILT) has emerged as a promising solution for designing and optimizing photo masks for integrated circuit fabrication. Relying on multi-beam mask writers, ILT enables the creation of free-form curvilinear mask shapes that enhance printed wafer image quality and process window. However, a major challenge in implementing curvilinear ILT for large-scale production is mask rule checking, an area currently under development by foundries and Electronic Design Automation (EDA) tool vendors.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts logic for curvilinear design retargeting in accordance with one embodiment.

FIG. 2 depicts differentiable morphological operation logic in accordance with one embodiment.

FIG. 3 depicts curvilinear inverse lithography logic in accordance with one embodiment.

FIG. 4 depicts an example of a disc-shaped structuring element.

FIG. 5 depicts visualization of morphological operators with eclipse structural elements, applied on binary images.

FIG. 6 depicts a parallel processing unit in accordance with one embodiment.

FIG. 7 depicts a general processing cluster in accordance with one embodiment.

FIG. 8 depicts a memory partition unit in accordance with one embodiment.

FIG. 9 depicts a streaming multiprocessor in accordance with one embodiment.

FIG. 10 depicts a processing system in accordance with one embodiment.

FIG. 11 depicts an exemplary processing system in accordance with another embodiment.

FIG. 12 depicts a graphics processing pipeline in accordance with one embodiment.

### DETAILED DESCRIPTION

Disclosed herein are mechanisms for inverse lithography that improve curvilinear masks by applying differentiable morphological operators. The disclosed mechanisms improve optimization convergence and enhance mask quality via application of curvilinear design retargeting to enable inverse lithography solver tools to optimize toward corner-smoothed targets, resulting in faster and improved convergence.

The disclosed mechanisms utilize a differentiable morphological operator that may be seamlessly integrated into legacy inverse lithography processes to control mask curvature and shape without compromising the final quality of results (QoR).

The disclosed mechanisms may provide faster convergence than traditional inverse lithography processes by utilizing curvilinear design retargeting. The disclosed mechanisms enable improved mask quality through the application of differentiable morphological operators in accordance with mask design rules. Additionally, by addressing inverse lithography-generated artifacts during the optimization process, the disclosed mechanisms obviate the application of unnecessary post-processing, preserving the optimized resist image quality. Traditional approaches apply strided average pooling to smooth the mask shape after each iteration's mask binarization step, introducing inaccuracies in the forward lithography calculations.

In some aspects, lithography functions as a low-pass filter. This is mathematically represented by the complex lithography kernels Hᵢ in Eq. 1 below. Each Hᵢ comprises coefficients that affect the entire frequency spectrum of the mask. However, the lithography kernel primarily captures information at locations associated with lower frequency components of the mask. Consequently, high-frequency details of the mask, such as corners, are not effectively transferred to the silicon. As a result, optimizing a mask solely for Manhattan-shaped corners is not feasible and can lead to suboptimal performance at other critical locations, ultimately compromising manufacturing process windows.

Edge-based optical proximity correction may involve adjusting the placement of critical dimension error measurement points to better guide the optical proximity correction process. Rather than positioning these measurement points directly on the polygon edge near corners—where they may lead to over-optimization—the disclosed mechanisms relocate the measurement points either inside the shape at convex corners, or outside the shape at concave corners. This adjustment enables the mask contour to align more effectively with the target during optical proximity correction, thereby reducing the risk of over-optimization and enlarging manufacturing process windows.

A goal of inverse lithography is to optimize an entire circuit layout image for manufacturing. Discrepancies between a generated resist pattern and the ideal circuit design may result in significant gradient values during optimization.

The magnitude of the gradients produced by the objective functions of inverse lithography models change during the training process. At later training stages, the gradients produced by the mismatch between polygon corner regions (e.g., ≈0.08% of the total design area) may for example contribute about 20% of the overall gradient value. Consequently, the training logic may focus excessively on objectives that are unattainable, leading to a negative impact on overall process variation tolerance.

TABLE 2
Notations and symbols used throughout this paper.

| Notation | Description |
|---|---|
| M | Mask image |
| M_{c} | Continuous tone mask image |
| Z* | Manhattan design target |
| Zᵣ* | Retargeted design target |
| X(i, j) | The entry of X given i, j index |
| X(i₁:i₂, j₁:j₂) | A sub-block of X given i₁, i₂, j₁, j₂ index |
| A⊗B | Convolution of A by B |
| A⊙B | Element-wise product between A and B |
| A⊕B | Dilation of A by the structuring element B |
| A⊖B | Erosion of A by the structuring element B |
| [symbol] (A) | The Fourier transform of A |

Herein, lowercase letters depict scalar parameters (e.g. x); bold lowercase letters depict vector parameters (e.g. x); and bold uppercase letters depict matrices (e.g. X). The notation X(i, j) depicts a single-entry matrix index; the notation X(i₁:i₂, j₁:j₂) indicates the index of a sub-matrix within a matrix (i.e., a block).

Forward lithography simulation comprises a process of lithographic mask optimization, modeling the lithographic process through a series of approximations. In some embodiments, this involves utilization of a Hopkin's Diffraction model along with a constant resist threshold, as expressed by the following:

$$I = {\sum }_{i = 1}^{k} {α}_{i} {\vert {ℱ}^{- 1} ( M ⊙ {H}_{i} ) \vert}_{2}^{2} \qquad Eq . 1$$

In this model, [symbol] ⁻¹(M) represents the rasterized mask image M in the Fourier domain, Hᵢ represents a lithography transmission kernel that is pre-configured to represents a specific lithography system configuration, and I is the aerial image comprising the light intensity pattern projected on the resist material. The parameters αᵢ are weights on the Fourier components. Through constant resist threshold modeling, the final resist image may be derived as follows:

$$Z ( i , j ) = \{ \begin{matrix}1 , & if I ( i , j ) \geq {D}_{th} \\ 0 , & if I ( i , j ) < {D}_{th}\end{matrix} \qquad Eq . 2$$

Inverse lithography modeling is thereby a process of generating a lithography mask M that results in a resist pattern Z that closely matches the intended circuit layout design Z*. In practical manufacturing, the lithographic system may not operate under ideal conditions, leading to process variations where the resist pattern is either larger (Zₒᵤₜₑᵣ) or smaller (Zᵢₙₙₑᵣ) than ideal. A robust inverse lithography process generates a mask that minimizes such process variations.

In a binary (e.g., black and white) configuration, M, Z∈{0, 1}. However, to make the mask optimization end-to-end differentiable during inverse lithography, the binary mask may be converted to a continuous tone mask via a sigmoid operation, such as:

$${M}_{c} = \frac{1}{1 + exp ( - {β}_{1} ( M - {M}_{s} )} \qquad Eq . 3$$

where β1 is the ‘mask steepness’ and Mₛ is a constant offset value that may be set for example to 0.5 for improved sub-resolution assist feature (SRAF) generation. Similarly, the resist image may also converted to the continuous tone domain, for example by:

$${Z}_{c} = \frac{1}{1 + exp ( - {β}_{2} ( I - {D}_{th} )} \qquad Eq . 4$$

Inverse lithography may be mathematically modeled as

$${min}_{M} f ( M , {Z}^{*} ) \qquad Eq . 5$$

subject to Eq. 1, Eq. 3, and Eq. 4 where ƒ is an objective function that satisfies inverse lithography quality-of-results requirements.

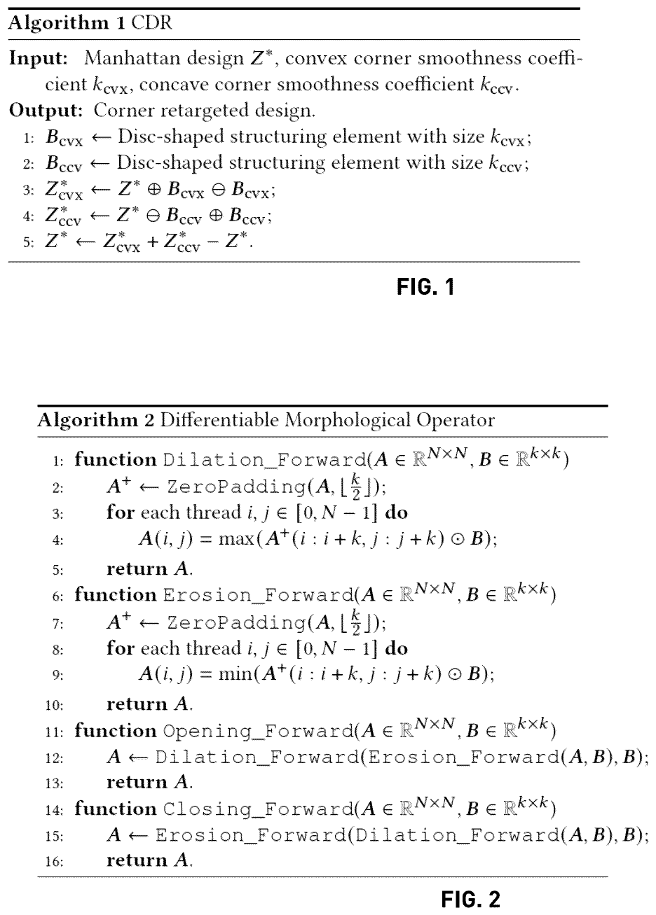

FIG. 1 depicts logic for curvilinear design retargeting in accordance with one embodiment.

The conventional approach of corner retargeting by moving critical dimension error measurement points may be inadequate for pixel-based optimization objectives. To address this issue, the disclosed mechanisms utilize curvilinear design retargeting to smooth original Manhattan design corners into curvilinear shapes, using the retargeted design as the objective for inverse lithography optimization.

Exemplary curvilinear design retargeting logic is depicted in Algorithm 1, applying opening and closing operation on the original Manhattan design respectively (lines 3-4), followed by merging the morphological effects together (line 5). An example can be found in FIG. 5, panel (f). Curvilinear design retargeting only modifies the vertex region of each polygon without changing the critical dimensions.

FIG. 2 depicts differentiable morphological operation logic in accordance with one embodiment.

Mask rules in inverse lithography are conventionally addressed through post-processing, during which artifacts generated by inverse lithography are manually removed. The disclosed mechanisms mitigate this inefficiency with an automated process for mask rule adherence. The properties of morphological operators may align to some extent with the requirements of curvilinear mask rules. For use in inverse lithography these operators may be implemented in a differentiable manner.

Embodiments of logic to implement dilation and erosion operators are depicted in Algorithm 2. These operators bear some similarity to convolution except that the summation over the sliding window is replaced with min (erosion) or max (dilation) operations. Opening and closing may be achieved via the operations expressed in Eq. (11) and Eq. (12).

Edge placement error violation and process variation band (PVB) are two metrics of mask lithography quality. Other metrics of mask lithography quality is mask shape area violation and mask shape distance violation (MSDV), which represent adherence to the curvilinear mask rules.

Edge placement error (EPE) quantifies the distance between the edges of the target resist design and the edges of the actual printed resist pattern on the wafer. When this distance exceeds a certain threshold, for example a few nanometers, the manufacture of the design is at risk of failing. Each instance where this threshold is surpassed in the printed resist pattern is referred to as an EPE violation. A well-optimized mask should minimize the occurrence of these EPE violations as much as possible.

The process variation band (PVB) defines how the printed resist image fluctuates due to variations in the manufacturing process. One approach to quantitatively assess this variation involves perturbing lithography simulation parameters such as the lens focus plane and ultraviolet dose intensity. The area between the innermost and outermost contours of the resulting printed resist images represents the PVB. A smaller PVB indicates greater manufacturing robustness of the mask against process variations. The disclosed mechanisms utilize additional metrics of PVB related to the mask shape itself. In particular, the disclosed mechanisms may utilize an isolated minimum shape area and minimum shape distance as metrics of mask manufacturability across process variations. These metrics may be determined in the context of curvilinear mask design.

The minimum shape area is the area (e.g., in nm²) of the isolated shapes in the mask. Smaller, isolated islands in particular may lead to process variations and mask manufacturing challenges. Minimum shape area (MSA) may be expressed as

$$MSA = min {\sum }_{( i , j ) ∈ {S}_{k}} M ( i , j ) ∀ k = 0 , 1 , … , N - 1 \qquad Eq . 6$$

where Sₖ denotes the k^{th} isolated shape in the mask M and N is the total number of the isolated shapes.

Similar to the minimum shape area, the proximity of shapes in the mask may affect PVB. A minimum shape distance (MSD) metric may quantify this spacing, such that

$$MSD = min distance ( {S}_{i} , {S}_{j} ) , ∀ i , j = 0 , 1 , … , N - 1 \qquad Eq . 7$$

where

$$dist ( {S}_{i} , {S}_{j} ) = min \sqrt{{( m - p )}^{2} + {( n - p )}^{2}} , \qquad Eq . 8$$

$$∀ ( m , n ) ∈ {S}_{i} , ( p , q ) ∈ {S}_{j}$$

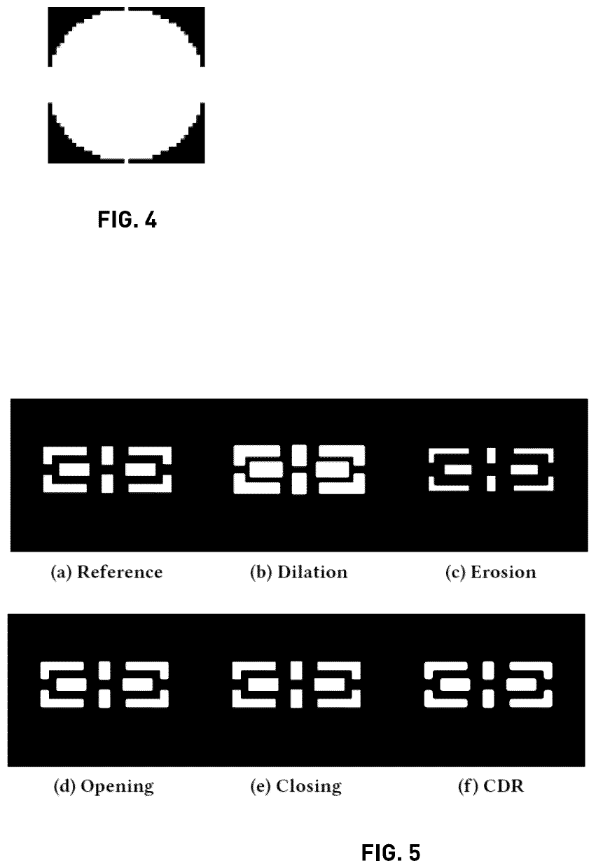

Morphological operators include erosion, dilation, opening, and closing. Each of these operators imposes different effects on binary geometrical images Herein the following notations are used to represent these morphological operators:

$$fe ( A , B ) = A ⊖ B , ( Erosion ) \qquad ( 9 )$$

$$fd ( A , B ) = A ⊕ B , ( Dilation ) \qquad ( 10 )$$

$$fo ( A , B ) = fd ( A , B ) ⊖ B , ( Opening ) \qquad ( 11 )$$

$$fc ( A , B ) = fe ( A , B ) ⊕ B , ( Closing ) \qquad ( 12 )$$

where A is the input and B is a predefined structuring element. In one embodiment, a disc shape (‘eclipse’) is applied as the structuring element, as exemplified in FIG. 4. The effects of applying the four morphological operators with the eclipse structuring element on a reference pattern (panel (a)) are depicted in FIG. 5.

FIG. 5 depicts visualizations of morphological operators with eclipse structural elements, applied on binary images. Panel (a) depicts original resist design image comprising Manhattan shapes. Panel (b) depicts the effects of dilation, which enlarges the shapes in the original image. Panel (c) depicts the effects of erosion, which ‘etches’ the original image and yields narrowed shapes. Panel (d) depicts the effects of opening, which rounds the convex corners of each shape. Panel (e) depicts the effects of closing, which rounds the concave corners of each shape. Panel (f) depicts the effects of curvilinear design retargeting, which rounds both the convex and concave corners of each shape.

Dilation of A by B results in the locus of B when the center of B traverses inside A (panel (b). Dilation merges shapes if their closest distance is smaller than the half diameter of the structuring element.

Erosion of A by B gives the locus of the center of B when B traverses inside A (panel (c). Erosion removes shapes smaller than the structuring element.

Opening and Closing operators (panels (d) and (c)) may be derived from combinations of dilation and erosion. Opening and Closing do not modify the critical dimension of Manhattan shapes provided that the structuring elements are properly configured.

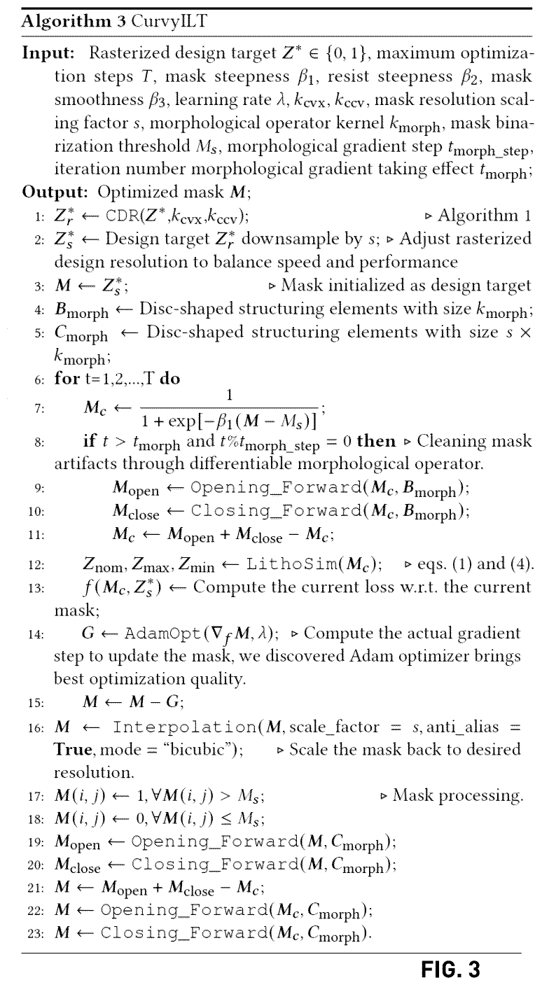

FIG. 3 depicts curvilinear inverse lithography logic in accordance with one embodiment. A conventional forward lithography process is carried out followed by the optimization objectives expressed in Eq. 5. The resist image mismatch is optimized under nominal conditions along with the process variation band, with the resist image mismatch being optimized based on the edge placement error metric. A parameter is utilized that implicitly improves the mask smoothness, due to the rule-violating artifacts and notches generated by inverse lithography being often related to perturbations in the high-frequency components of the mask. The optimization process of Eq. 5 may therefore be represented as three terms,

$$f ( M , Z \text{*)} = \vert {Z}_{nom} - Z * {\vert}_{2}^{2} + {\vert {Z}_{m ax} - {Z}_{m i n} \vert}_{2}^{2} + {β}_{3} {\vert ℱ ( M ) ( k : ; k : ) \vert}_{2}^{2}$$

where Zₙₒₘ, Zₘᵢₙ, and Zₘₐₓ are resist images derived through the processes expressed in Eq. 1 and Eq. 4 under different process conditions (e.g., varied optical lithography kernels Hᵢ). Parameter F(Mc) (k:; k:) represents the Fourier transform of the continuous-tone mask image after dropping (e.g., filtering out) the k smallest (less contributive) frequency modes. Parameter β₃ is an empirically determined parameter at the scale of 1e-3) that controls the mask's smoothness (the aforementioned smoothness parameter).

Configured in this manner, the optimization function ƒ(M, Z*) is continuous and differentiable so that inverse lithography in accordance with the disclosed mechanisms may be implemented using a gradient-based process. In one embodiment, an Adam optimizer is applied to improve convergence of the gradients.

The curvilinear inverse lithography algorithm embodied in Algorithm 3 may be understood to comprise three phases. The first phase comprises preprocessing including curvilinear design retargeting (line 1) and mask initialization (lines 2-3). The second phase comprises the primary optimization actions to update the lithography mask iteratively until a maximum optimization condition is reached (lines 5-16). During each optimization iteration, the process applies morphological operators on the mask image to perform corner smoothing (lines 8-10) and remove artifacts (lines 11-12). An Adam optimizer is invoked to determine true mask gradients and mask update steps for best practices (lines 13-16).

The third phase involves post-processing whereby the mask image is scaled to a desired resolution through interpolation and binarized with a preset threshold (lines 17-19).

The mechanisms disclosed herein may be implemented in and/or by computing devices utilizing one or more graphic processing unit (GPU), and/or general purpose data processor (e.g., a “central processing unit” or CPU), and/or a CPU with an integrated graphics processor. For example, the disclosed mechanisms may be implemented as machine-readable and executable instructions stored by non-volatile memories and/or media. Exemplary architectures will now be described that may be configured to implement the mechanisms disclosed herein.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

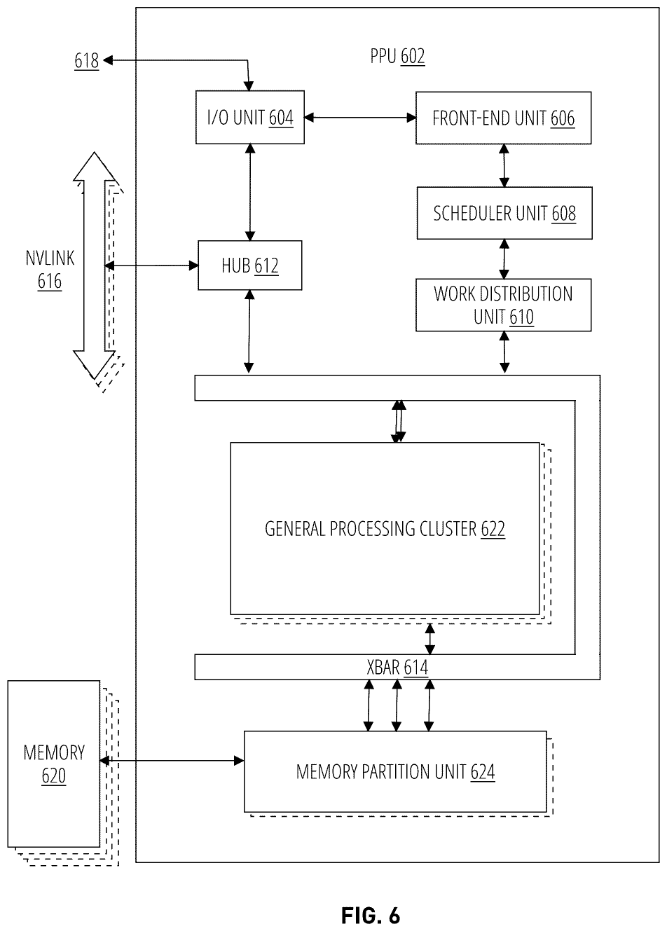

FIG. 6 depicts a parallel processing unit 602, in accordance with an embodiment. In an embodiment, the parallel processing unit 602 is a multi-threaded processor that is implemented on one or more integrated circuit devices. The parallel processing unit 602 is a latency hiding architecture designed to process many threads in parallel. A thread (e.g., a thread of execution) is an instantiation of a set of instructions configured to be executed by the parallel processing unit 602. In an embodiment, the parallel processing unit 602 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 602 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 602 modules may be configured to accelerate thousands of High Performance Computing (HPC), data center, and machine learning applications. The parallel processing unit 602 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 6, the parallel processing unit 602 includes an I/O unit 604, a front-end unit 606, a scheduler unit 608, a work distribution unit 610, a hub 612, a crossbar 614, one or more general processing cluster 622 modules, and one or more memory partition unit 624 modules. The parallel processing unit 602 may be connected to a host processor or other parallel processing unit 602 modules via one or more high-speed NVLink 616 interconnects. The parallel processing unit 602 may be connected to a host processor or other peripheral devices via an interconnect 618. The parallel processing unit 602 may also be connected to a local memory comprising a number of memory 620 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 620 may comprise logic to configure the parallel processing unit 602 to carry out aspects of the techniques disclosed herein.

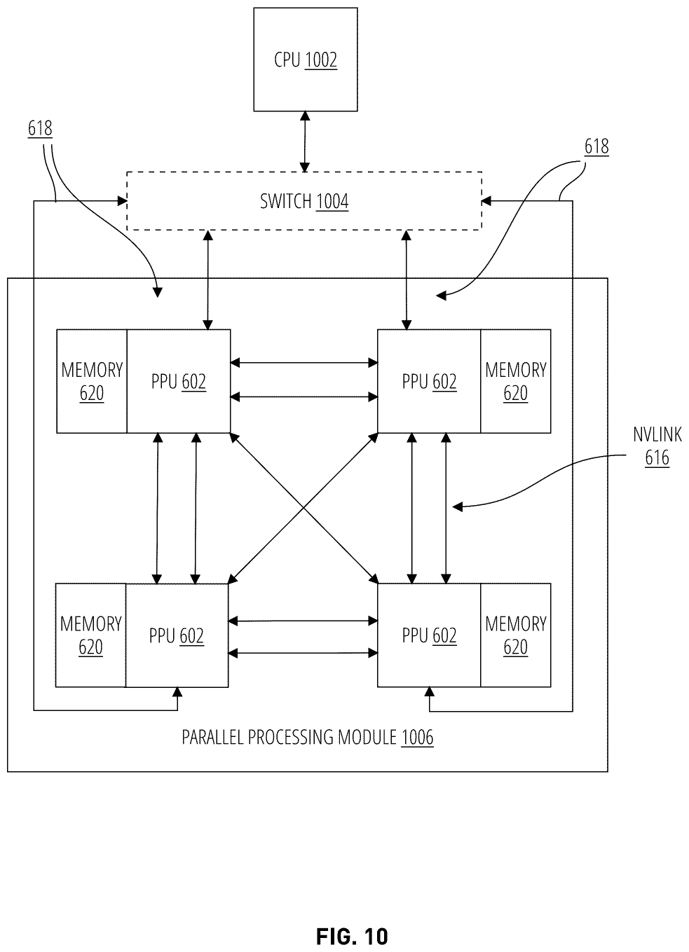

The NVLink 616 interconnect enables systems to scale and include one or more parallel processing unit 602 modules combined with one or more CPUs, supports cache coherence between the parallel processing unit 602 modules and CPUs, and CPU mastering. Data and/or commands may be transmitted by the NVLink 616 through the hub 612 to/from other units of the parallel processing unit 602 such as one or more copy engines, a video encoder, a video decoder, a power management unit, etc. (not explicitly shown). The NVLink 616 is described in more detail in conjunction with FIG. 10.

The I/O unit 604 is configured to transmit and receive communications (e.g., commands, data, etc.) from a host processor (not shown) over the interconnect 618. The I/O unit 604 may communicate with the host processor directly via the interconnect 618 or through one or more intermediate devices such as a memory bridge. In an embodiment, the I/O unit 604 may communicate with one or more other processors, such as one or more parallel processing unit 602 modules via the interconnect 618. In an embodiment, the I/O unit 604 implements a Peripheral Component Interconnect Express (PCIe) interface for communications over a PCIe bus and the interconnect 618 is a PCIe bus. In alternative embodiments, the I/O unit 604 may implement other types of well-known interfaces for communicating with external devices.

The I/O unit 604 decodes packets received via the interconnect 618. In an embodiment, the packets represent commands configured to cause the parallel processing unit 602 to perform various operations. The I/O unit 604 transmits the decoded commands to various other units of the parallel processing unit 602 as the commands may specify. For example, some commands may be transmitted to the front-end unit 606. Other commands may be transmitted to the hub 612 or other units of the parallel processing unit 602 such as one or more copy engines, a video encoder, a video decoder, a power management unit, etc. (not explicitly shown). In other words, the I/O unit 604 is configured to route communications between and among the various logical units of the parallel processing unit 602.

In an embodiment, a program executed by the host processor encodes a command stream in a buffer that provides workloads to the parallel processing unit 602 for processing. A workload may comprise several instructions and data to be processed by those instructions. The buffer is a region in a memory that is accessible (e.g., read/write) by both the host processor and the parallel processing unit 602. For example, the I/O unit 604 may be configured to access the buffer in a system memory connected to the interconnect 618 via memory requests transmitted over the interconnect 618. In an embodiment, the host processor writes the command stream to the buffer and then transmits a pointer to the start of the command stream to the parallel processing unit 602. The front-end unit 606 receives pointers to one or more command streams. The front-end unit 606 manages the one or more streams, reading commands from the streams and forwarding commands to the various units of the parallel processing unit 602.

The front-end unit 606 is coupled to a scheduler unit 608 that configures the various general processing cluster 622 modules to process tasks defined by the one or more streams. The scheduler unit 608 is configured to track state information related to the various tasks managed by the scheduler unit 608. The state may indicate which general processing cluster 622 a task is assigned to, whether the task is active or inactive, a priority level associated with the task, and so forth. The scheduler unit 608 manages the execution of a plurality of tasks on the one or more general processing cluster 622 modules.

The scheduler unit 608 is coupled to a work distribution unit 610 that is configured to dispatch tasks for execution on the general processing cluster 622 modules. The work distribution unit 610 may track a number of scheduled tasks received from the scheduler unit 608. In an embodiment, the work distribution unit 610 manages a pending task pool and an active task pool for each of the general processing cluster 622 modules. The pending task pool may comprise a number of slots (e.g., 32 slots) that contain tasks assigned to be processed by a particular general processing cluster 622. The active task pool may comprise a number of slots (e.g., 4 slots) for tasks that are actively being processed by the general processing cluster 622 modules. As a general processing cluster 622 finishes the execution of a task, that task is evicted from the active task pool for the general processing cluster 622 and one of the other tasks from the pending task pool is selected and scheduled for execution on the general processing cluster 622. If an active task has been idle on the general processing cluster 622, such as while waiting for a data dependency to be resolved, then the active task may be evicted from the general processing cluster 622 and returned to the pending task pool while another task in the pending task pool is selected and scheduled for execution on the general processing cluster 622.

The work distribution unit 610 communicates with the one or more general processing cluster 622 modules via crossbar 614. The crossbar 614 is an interconnect network that couples many of the units of the parallel processing unit 602 to other units of the parallel processing unit 602. For example, the crossbar 614 may be configured to couple the work distribution unit 610 to a particular general processing cluster 622. Although not shown explicitly, one or more other units of the parallel processing unit 602 may also be connected to the crossbar 614 via the hub 612.

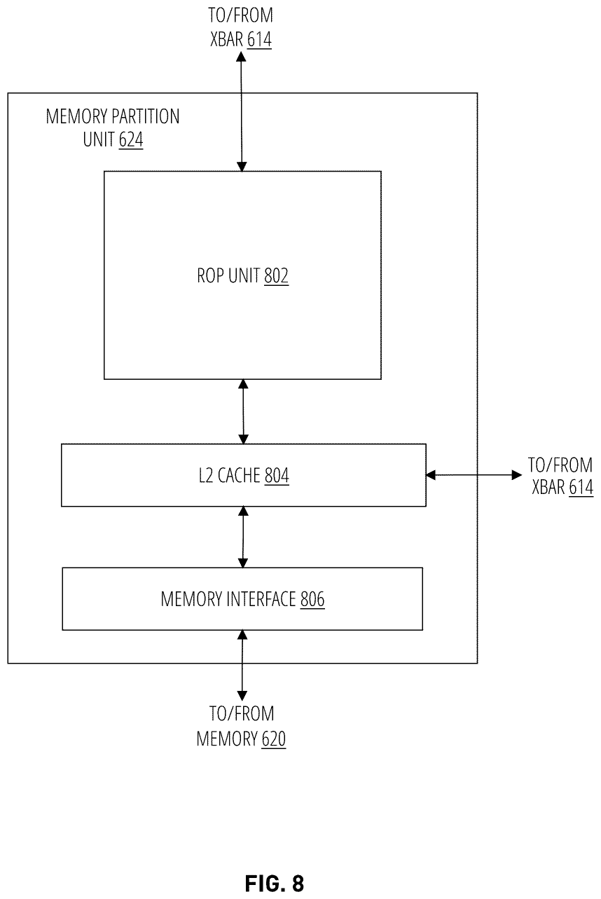

The tasks are managed by the scheduler unit 608 and dispatched to a general processing cluster 622 by the work distribution unit 610. The general processing cluster 622 is configured to process the task and generate results. The results may be consumed by other tasks within the general processing cluster 622, routed to a different general processing cluster 622 via the crossbar 614, or stored in the memory 620. The results can be written to the memory 620 via the memory partition unit 624 modules, which implement a memory interface for reading and writing data to/from the memory 620. The results can be transmitted to another parallel processing unit 602 or CPU via the NVLink 616. In an embodiment, the parallel processing unit 602 includes a number U of memory partition unit 624 modules that is equal to the number of separate and distinct memory 620 devices coupled to the parallel processing unit 602. A memory partition unit 624 will be described in more detail below in conjunction with FIG. 8.

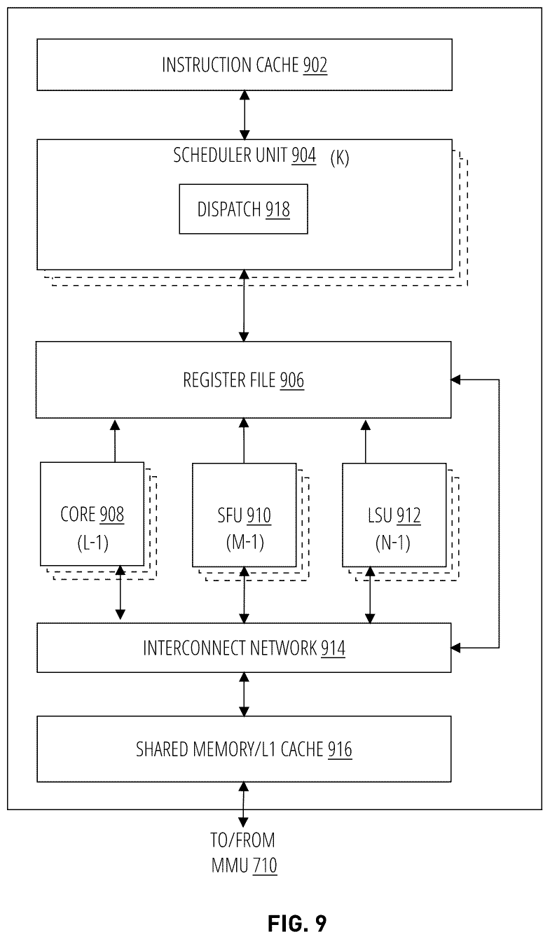

In an embodiment, a host processor executes a driver kernel that implements an application programming interface (API) that enables one or more applications executing on the host processor to schedule operations for execution on the parallel processing unit 602. In an embodiment, multiple compute applications are simultaneously executed by the parallel processing unit 602 and the parallel processing unit 602 provides isolation, quality of service (QoS), and independent address spaces for the multiple compute applications. An application may generate instructions (e.g., API calls) that cause the driver kernel to generate one or more tasks for execution by the parallel processing unit 602. The driver kernel outputs tasks to one or more streams being processed by the parallel processing unit 602. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 9.

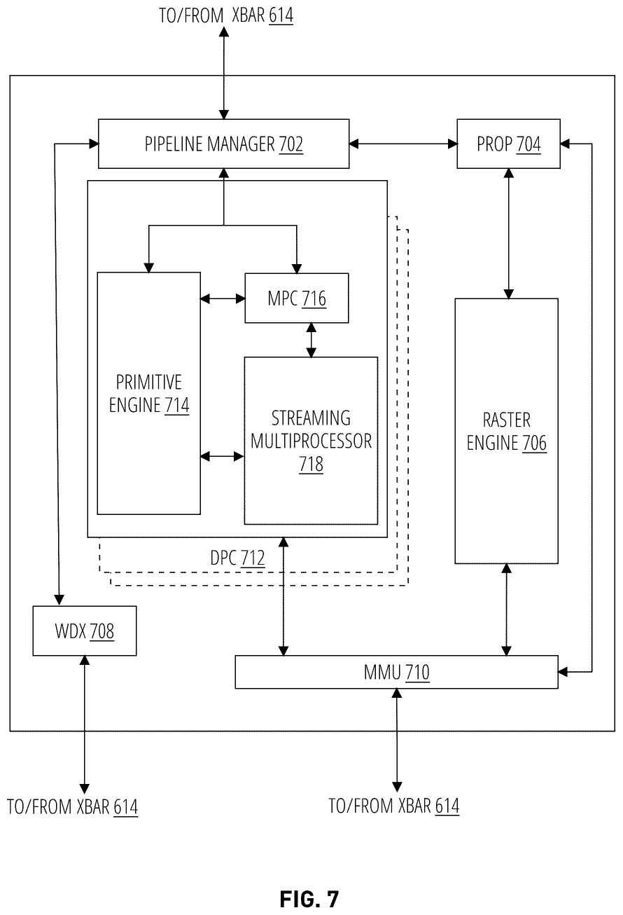

FIG. 7 depicts a general processing cluster 622 of the parallel processing unit 602 of FIG. 6, in accordance with an embodiment. As shown in FIG. 7, each general processing cluster 622 includes a number of hardware units for processing tasks. In an embodiment, each general processing cluster 622 includes a pipeline manager 702, a pre-raster operations unit 704, a raster engine 706, a work distribution crossbar 708, a memory management unit 710, and one or more data processing cluster 712. It will be appreciated that the general processing cluster 622 of FIG. 7 may include other hardware units in lieu of or in addition to the units shown in FIG. 7.

In an embodiment, the operation of the general processing cluster 622 is controlled by the pipeline manager 702. The pipeline manager 702 manages the configuration of the one or more data processing cluster 712 modules for processing tasks allocated to the general processing cluster 622. In an embodiment, the pipeline manager 702 may configure at least one of the one or more data processing cluster 712 modules to implement at least a portion of a graphics rendering pipeline. For example, a data processing cluster 712 may be configured to execute a vertex shader program on the programmable streaming multiprocessor 718. The pipeline manager 702 may also be configured to route packets received from the work distribution unit 610 to the appropriate logical units within the general processing cluster 622. For example, some packets may be routed to fixed function hardware units in the pre-raster operations unit 704 and/or raster engine 706 while other packets may be routed to the data processing cluster 712 modules for processing by the primitive engine 714 or the streaming multiprocessor 718. In an embodiment, the pipeline manager 702 may configure at least one of the one or more data processing cluster 712 modules to implement a neural network model and/or a computing pipeline.

The pre-raster operations unit 704 is configured to route data generated by the raster engine 706 and the data processing cluster 712 modules to a Raster Operations (ROP) unit, described in more detail in conjunction with FIG. 8. The pre-raster operations unit 704 may also be configured to perform optimizations for color blending, organize pixel data, perform address translations, and the like.

The raster engine 706 includes a number of fixed function hardware units configured to perform various raster operations. In an embodiment, the raster engine 706 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 706 comprises fragments to be processed, for example, by a fragment shader implemented within a data processing cluster 712.

Each data processing cluster 712 included in the general processing cluster 622 includes an M-pipe controller 716, a primitive engine 714, and one or more streaming multiprocessor 718 modules. The M-pipe controller 716 controls the operation of the data processing cluster 712, routing packets received from the pipeline manager 702 to the appropriate units in the data processing cluster 712. For example, packets associated with a vertex may be routed to the primitive engine 714, which is configured to fetch vertex attributes associated with the vertex from the memory 620. In contrast, packets associated with a shader program may be transmitted to the streaming multiprocessor 718.

The streaming multiprocessor 718 comprises a programmable streaming processor that is configured to process tasks represented by a number of threads. Each streaming multiprocessor 718 is multi-threaded and configured to execute a plurality of threads (e.g., 32 threads) from a particular group of threads concurrently. In an embodiment, the streaming multiprocessor 718 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 718 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 718 will be described in more detail below in conjunction with FIG. 9.

The memory management unit 710 provides an interface between the general processing cluster 622 and the memory partition unit 624. The memory management unit 710 may provide translation of virtual addresses into physical addresses, memory protection, and arbitration of memory requests. In an embodiment, the memory management unit 710 provides one or more translation lookaside buffers (TLBs) for performing translation of virtual addresses into physical addresses in the memory 620.

FIG. 8 depicts a memory partition unit 624 of the parallel processing unit 602 of FIG. 6, in accordance with an embodiment. As shown in FIG. 8, the memory partition unit 624 includes a raster operations unit 802, a level two cache 804, and a memory interface 806. The memory interface 806 is coupled to the memory 620. Memory interface 806 may implement 32, 64, 128, 1024-bit data buses, or the like, for high-speed data transfer. In an embodiment, the parallel processing unit 602 incorporates U memory interface 806 modules, one memory interface 806 per pair of memory partition unit 624 modules, where each pair of memory partition unit 624 modules is connected to a corresponding memory 620 device. For example, parallel processing unit 602 may be connected to up to Y memory 620 devices, such as high bandwidth memory stacks or graphics double-data-rate, version 5, synchronous dynamic random access memory, or other types of persistent storage.

In an embodiment, the memory interface 806 implements an HBM2 memory interface and Y equals half U. In an embodiment, the HBM2 memory stacks are located on the same physical package as the parallel processing unit 602, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 620 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 602 modules process very large datasets and/or run applications for extended periods.

In an embodiment, the parallel processing unit 602 implements a multi-level memory hierarchy. In an embodiment, the memory partition unit 624 supports a unified memory to provide a single unified virtual address space for CPU and parallel processing unit 602 memory, enabling data sharing between virtual memory systems. In an embodiment the frequency of accesses by a parallel processing unit 602 to memory located on other processors is traced to ensure that memory pages are moved to the physical memory of the parallel processing unit 602 that is accessing the pages more frequently. In an embodiment, the NVLink 616 supports address translation services allowing the parallel processing unit 602 to directly access a CPU's page tables and providing full access to CPU memory by the parallel processing unit 602.

In an embodiment, copy engines transfer data between multiple parallel processing unit 602 modules or between parallel processing unit 602 modules and CPUs. The copy engines can generate page faults for addresses that are not mapped into the page tables. The memory partition unit 624 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 620 or other system memory may be fetched by the memory partition unit 624 and stored in the level two cache 804, which is located on-chip and is shared between the various general processing cluster 622 modules. As shown, each memory partition unit 624 includes a portion of the level two cache 804 associated with a corresponding memory 620 device. Lower level caches may then be implemented in various units within the general processing cluster 622 modules. For example, each of the streaming multiprocessor 718 modules may implement an L1 cache. The L1 cache is private memory that is dedicated to a particular streaming multiprocessor 718. Data from the level two cache 804 may be fetched and stored in each of the L1 caches for processing in the functional units of the streaming multiprocessor 718 modules. The level two cache 804 is coupled to the memory interface 806 and the crossbar 614.

The raster operations unit 802 performs graphics raster operations related to pixel color, such as color compression, pixel blending, and the like. The raster operations unit 802 also implements depth testing in conjunction with the raster engine 706, receiving a depth for a sample location associated with a pixel fragment from the culling engine of the raster engine 706. The depth is tested against a corresponding depth in a depth buffer for a sample location associated with the fragment. If the fragment passes the depth test for the sample location, then the raster operations unit 802 updates the depth buffer and transmits a result of the depth test to the raster engine 706. It will be appreciated that the number of partition memory partition unit 624 modules may be different than the number of general processing cluster 622 modules and, therefore, each raster operations unit 802 may be coupled to each of the general processing cluster 622 modules. The raster operations unit 802 tracks packets received from the different general processing cluster 622 modules and determines which general processing cluster 1 that a result generated by the raster operations unit 802 is routed to through the crossbar 614. Although the raster operations unit 802 is included within the memory partition unit 624 in FIG. 8, in other embodiment, the raster operations unit 802 may be outside of the memory partition unit 624. For example, the raster operations unit 802 may reside in the general processing cluster 622 or another unit.

FIG. 9 illustrates the streaming multiprocessor 718 of FIG. 7, in accordance with an embodiment. As shown in FIG. 9, the streaming multiprocessor 718 includes an instruction cache 902, one or more scheduler unit 904 modules (e.g., such as scheduler unit 608), a register file 906, one or more processing core 908 modules, one or more special function unit 910 modules, one or more load/store unit 912 modules, an interconnect network 914, and a shared memory/L1 cache 916.

As described above, the work distribution unit 610 dispatches tasks for execution on the general processing cluster 622 modules of the parallel processing unit 602. The tasks are allocated to a particular data processing cluster 712 within a general processing cluster 622 and, if the task is associated with a shader program, the task may be allocated to a streaming multiprocessor 718. The scheduler unit 608 receives the tasks from the work distribution unit 610 and manages instruction scheduling for one or more thread blocks assigned to the streaming multiprocessor 718. The scheduler unit 904 schedules thread blocks for execution as warps of parallel threads, where each thread block is allocated at least one warp. In an embodiment, each warp executes 32 threads. The scheduler unit 904 may manage a plurality of different thread blocks, allocating the warps to the different thread blocks and then dispatching instructions from the plurality of different cooperative groups to the various functional units (e.g., core 908 modules, special function unit 910 modules, and load/store unit 912 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 918 unit is configured within the scheduler unit 904 to transmit instructions to one or more of the functional units. In one embodiment, the scheduler unit 904 includes two dispatch 918 units that enable two different instructions from the same warp to be dispatched during each clock cycle. In alternative embodiments, each scheduler unit 904 may include a single dispatch 918 unit or additional dispatch 918 units.

Each streaming multiprocessor 718 includes a register file 906 that provides a set of registers for the functional units of the streaming multiprocessor 718. In an embodiment, the register file 906 is divided between each of the functional units such that each functional unit is allocated a dedicated portion of the register file 906. In another embodiment, the register file 906 is divided between the different warps being executed by the streaming multiprocessor 718. The register file 906 provides temporary storage for operands connected to the data paths of the functional units.

Each streaming multiprocessor 718 comprises L processing core 908 modules. In an embodiment, the streaming multiprocessor 718 includes a large number (e.g., 128, etc.) of distinct processing core 908 modules. Each core 908 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 908 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 908 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 718 also comprises M special function unit 910 modules that perform special functions (e.g., attribute evaluation, reciprocal square root, and the like). In an embodiment, the special function unit 910 modules may include a tree traversal unit configured to traverse a hierarchical tree data structure. In an embodiment, the special function unit 910 modules may include texture unit configured to perform texture map filtering operations. In an embodiment, the texture units are configured to load texture maps (e.g., a 2D array of texels) from the memory 620 and sample the texture maps to produce sampled texture values for use in shader programs executed by the streaming multiprocessor 718. In an embodiment, the texture maps are stored in the shared memory/L1 cache 916. The texture units implement texture operations such as filtering operations using mip-maps (e.g., texture maps of varying levels of detail). In an embodiment, each streaming multiprocessor 718 includes two texture units.

Each streaming multiprocessor 718 also comprises N load/store unit 912 modules that implement load and store operations between the shared memory/L1 cache 916 and the register file 906. Each streaming multiprocessor 718 includes an interconnect network 914 that connects each of the functional units to the register file 906 and the load/store unit 912 to the register file 906 and shared memory/L1 cache 916. In an embodiment, the interconnect network 914 is a crossbar that can be configured to connect any of the functional units to any of the registers in the register file 906 and connect the load/store unit 912 modules to the register file 906 and memory locations in shared memory/L1 cache 916.

The shared memory/L1 cache 916 is an array of on-chip memory that allows for data storage and communication between the streaming multiprocessor 718 and the primitive engine 714 and between threads in the streaming multiprocessor 718. In an embodiment, the shared memory/L1 cache 916 comprises 128 KB of storage capacity and is in the path from the streaming multiprocessor 718 to the memory partition unit 624. The shared memory/L1 cache 916 can be used to cache reads and writes. One or more of the shared memory/L1 cache 916, level two cache 804, and memory 620 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 916 enables the shared memory/L1 cache 916 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 6, are bypassed, creating a much simpler programming model. In the general purpose parallel computation configuration, the work distribution unit 610 assigns and distributes blocks of threads directly to the data processing cluster 712 modules. The threads in a block execute the same program, using a unique thread ID in the calculation to ensure each thread generates unique results, using the streaming multiprocessor 718 to execute the program and perform calculations, shared memory/L1 cache 916 to communicate between threads, and the load/store unit 912 to read and write global memory through the shared memory/L1 cache 916 and the memory partition unit 624. When configured for general purpose parallel computation, the streaming multiprocessor 718 can also write commands that the scheduler unit 608 can use to launch new work on the data processing cluster 712 modules.

The parallel processing unit 602 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 602 is embodied on a single semiconductor substrate. In another embodiment, the parallel processing unit 602 is included in a system-on-a-chip (SoC) along with one or more other devices such as additional parallel processing unit 602 modules, the memory 620, a reduced instruction set computer (RISC) CPU, a memory management unit (MMU), a digital-to-analog converter (DAC), and the like.

In an embodiment, the parallel processing unit 602 may be included on a graphics card that includes one or more memory devices. The graphics card may be configured to interface with a PCIe slot on a motherboard of a desktop computer. In yet another embodiment, the parallel processing unit 602 may be an integrated graphics processing unit (iGPU) or parallel processor included in the chipset of the motherboard.

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 10 is a conceptual diagram of a processing system implemented using the parallel processing unit 602 of FIG. 6, in accordance with an embodiment. The processing system includes a central processing unit 1002, a switch 1004, and multiple parallel processing unit 602 modules each and respective memory 620 modules. The switch 1004 is depicted with dashed lines, indicating that it is optional in some embodiments.

The NVLink 616 provides high-speed communication links between each of the parallel processing unit 602 modules. Although a particular number of NVLink 616 and interconnect 618 connections are illustrated in FIG. 10, the number of connections to each parallel processing unit 602 and the central processing unit 1002 may vary. The switch 1004 interfaces between the interconnect 618 and the central processing unit 1002. The parallel processing unit 602 modules, memory 620 modules, and NVLink 616 connections may be situated on a single semiconductor platform to form a parallel processing module 1006. In an embodiment, the switch 1004 supports two or more protocols to interface between various different connections and/or links.

In another embodiment (not shown), the NVLink 616 provides one or more high-speed communication links between each of the parallel processing unit modules (parallel processing unit 602, parallel processing unit 602, parallel processing unit 602, and parallel processing unit 602) and the central processing unit 1002 and the switch 1004 (when present) interfaces between the interconnect 618 and each of the parallel processing unit modules. The parallel processing unit modules, memory 620 modules, and interconnect 618 may be situated on a single semiconductor platform to form a parallel processing module 1006. In yet another embodiment (not shown), the interconnect 618 provides one or more communication links between each of the parallel processing unit modules and the central processing unit 1002 and the switch 1004 interfaces between each of the parallel processing unit modules using the NVLink 616 to provide one or more high-speed communication links between the parallel processing unit modules. In another embodiment (not shown), the NVLink 616 provides one or more high-speed communication links between the parallel processing unit modules and the central processing unit 1002 through the switch 1004. In yet another embodiment (not shown), the interconnect 618 provides one or more communication links between each of the parallel processing unit modules directly. One or more of the NVLink 616 high-speed communication links may be implemented as a physical NVLink interconnect or either an on-chip or on-die interconnect using the same protocol as the NVLink 616.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 1006 may be implemented as a circuit board substrate and each of the parallel processing unit modules and/or memory 620 modules may be packaged devices. In an embodiment, the central processing unit 1002, switch 1004, and the parallel processing module 1006 are situated on a single semiconductor platform.

In an embodiment, each parallel processing unit module includes six NVLink 616 interfaces (as shown in FIG. 10, five NVLink 616 interfaces are included for each parallel processing unit module). The NVLink 616 may be operated exclusively for PPU-to-PPU communication as shown in FIG. 10, or some combination of PPU-to-PPU and PPU-to-CPU, when the central processing unit 1002 also includes one or more NVLink 616 interfaces.

In an embodiment, the NVLink 616 allows direct load/store/atomic access from the central processing unit 1002 to each parallel processing unit module's memory 620. In an embodiment, the NVLink 616 supports coherency operations, allowing data read from the memory 620 modules to be stored in the cache hierarchy of the central processing unit 1002, reducing cache access latency for the central processing unit 1002. In an embodiment, the NVLink 616 includes support for Address Translation Services (ATS), enabling the parallel processing unit module to directly access page tables within the central processing unit 1002. One or more of the NVLink 616 may also be configured to operate in a low-power mode.

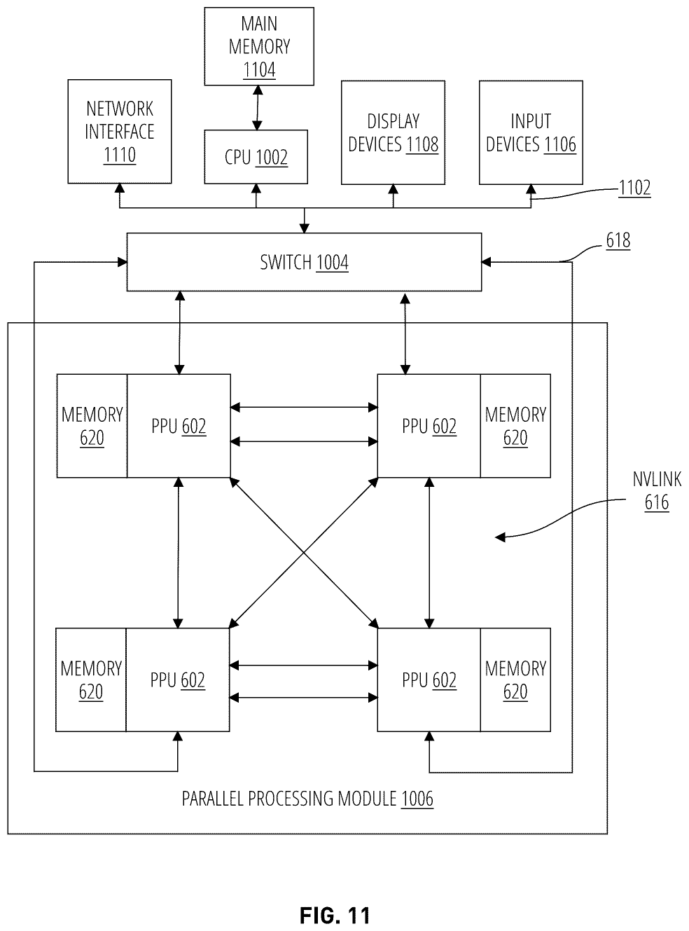

FIG. 11 depicts an exemplary processing system in which the various architecture and/or functionality of the various previous embodiments may be implemented. As shown, an exemplary processing system is provided including at least one central processing unit 1002 that is connected to a communications bus 1102. The communication communications bus 1102 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system also includes a main memory 1104. Control logic (software) and data are stored in the main memory 1104 which may take the form of random access memory (RAM). For simplicity of illustration, the main memory 1104 may be understood to comprise other forms of bulk memory, including non-volatile memory technologies.

The exemplary processing system also includes input devices 1106, the parallel processing module 1006, and display devices 1108, e.g. a conventional CRT (cathode ray tube), LCD (liquid crystal display), LED (light emitting diode), plasma display or the like. User input may be received from the input devices 1106, e.g., keyboard, mouse, touchpad, microphone, and the like. Each of the foregoing modules and/or devices may even be situated on a single semiconductor platform to form the exemplary processing system. Alternately, the various modules may also be situated separately or in various combinations of semiconductor platforms per the desires of the user.

Further, the exemplary processing system may be coupled to a network (e.g., a telecommunications network, local area network (LAN), wireless network, wide area network (WAN) such as the Internet, peer-to-peer network, cable network, or the like) through a network interface 1110 for communication purposes.

The exemplary processing system may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 1104 and/or the secondary storage. Such computer programs, when executed, enable the exemplary processing system to perform various functions. The main memory 1104, the storage, and/or any other storage are possible examples of computer-readable media (volatile and/or non-volatile, depending on the implementation).

The architecture and/or functionality of the various previous figures may be implemented in the context of a general computer system, a circuit board system, a game console system dedicated for entertainment purposes, an application-specific system, and/or any other desired system. For example, the exemplary processing system may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

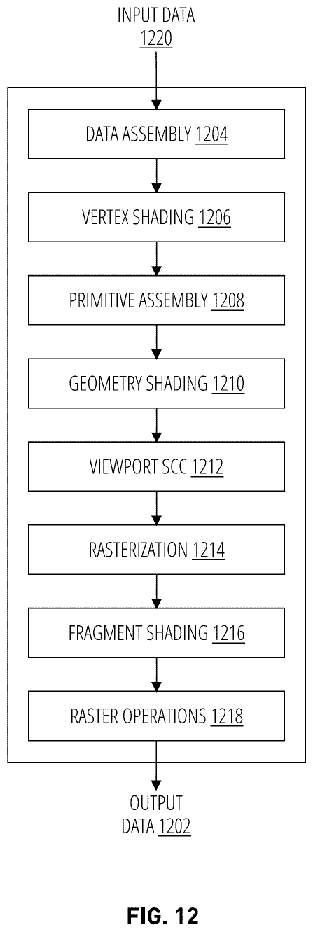

FIG. 12 is a conceptual diagram of a graphics processing pipeline implemented by the parallel processing unit 602 of FIG. 6, in accordance with an embodiment. In an embodiment, the parallel processing unit 602 comprises a graphics processing unit (GPU). The parallel processing unit 602 is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The parallel processing unit 602 can be configured to process the graphics primitives to generate a frame buffer (e.g., pixel data for each of the pixels of the display).

An application writes model data for a scene (e.g., a collection of vertices and attributes) to a memory such as a system memory or memory 620. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the streaming multiprocessor 718 modules of the parallel processing unit 602 including one or more of a vertex shader, hull shader, domain shader, geometry shader, and a pixel shader. For example, one or more of the streaming multiprocessor 718 modules may be configured to execute a vertex shader program that processes a number of vertices defined by the model data. In an embodiment, the different streaming multiprocessor 718 modules may be configured to execute different shader programs concurrently. For example, a first subset of streaming multiprocessor 718 modules may be configured to execute a vertex shader program while a second subset of streaming multiprocessor 718 modules may be configured to execute a pixel shader program. The first subset of streaming multiprocessor 718 modules processes vertex data to produce processed vertex data and writes the processed vertex data to the level two cache 804 and/or the memory 620. After the processed vertex data is rasterized (e.g., transformed from three-dimensional data into two-dimensional data in screen space) to produce fragment data, the second subset of streaming multiprocessor 718 modules executes a pixel shader to produce processed fragment data, which is then blended with other processed fragment data and written to the frame buffer in memory 620. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

The graphics processing pipeline is an abstract flow diagram of the processing steps implemented to generate 2D computer-generated images from 3D geometry data. As is well-known, pipeline architectures may perform long latency operations more efficiently by splitting up the operation into a plurality of stages, where the output of each stage is coupled to the input of the next successive stage. Thus, the graphics processing pipeline receives input data 601 that is transmitted from one stage to the next stage of the graphics processing pipeline to generate output data 1202. In an embodiment, the graphics processing pipeline may represent a graphics processing pipeline defined by the OpenGL® API. As an option, the graphics processing pipeline may be implemented in the context of the functionality and architecture of the previous Figures and/or any subsequent Figure(s).

As shown in FIG. 12, the graphics processing pipeline comprises a pipeline architecture that includes a number of stages. The stages include, but are not limited to, a data assembly 1204 stage, a vertex shading 1206 stage, a primitive assembly 1208 stage, a geometry shading 1210 stage, a viewport SCC 1212 stage, a rasterization 1214 stage, a fragment shading 1216 stage, and a raster operations 1218 stage. In an embodiment, the input data 1220 comprises commands that configure the processing units to implement the stages of the graphics processing pipeline and geometric primitives (e.g., points, lines, triangles, quads, triangle strips or fans, etc.) to be processed by the stages. The output data 1202 may comprise pixel data (e.g., color data) that is copied into a frame buffer or other type of surface data structure in a memory.

The data assembly 1204 stage receives the input data 1220 that specifies vertex data for high-order surfaces, primitives, or the like. The data assembly 1204 stage collects the vertex data in a temporary storage or queue, such as by receiving a command from the host processor that includes a pointer to a buffer in memory and reading the vertex data from the buffer. The vertex data is then transmitted to the vertex shading 1206 stage for processing.

The vertex shading 1206 stage processes vertex data by performing a set of operations (e.g., a vertex shader or a program) once for each of the vertices. Vertices may be, e.g., specified as a 4-coordinate vector (e.g., <x, y, z, w>) associated with one or more vertex attributes (e.g., color, texture coordinates, surface normal, etc.). The vertex shading 1206 stage may manipulate individual vertex attributes such as position, color, texture coordinates, and the like. In other words, the vertex shading 1206 stage performs operations on the vertex coordinates or other vertex attributes associated with a vertex. Such operations commonly including lighting operations (e.g., modifying color attributes for a vertex) and transformation operations (e.g., modifying the coordinate space for a vertex). For example, vertices may be specified using coordinates in an object-coordinate space, which are transformed by multiplying the coordinates by a matrix that translates the coordinates from the object-coordinate space into a world space or a normalized-device-coordinate (NCD) space. The vertex shading 1206 stage generates transformed vertex data that is transmitted to the primitive assembly 1208 stage.

The primitive assembly 1208 stage collects vertices output by the vertex shading 1206 stage and groups the vertices into geometric primitives for processing by the geometry shading 1210 stage. For example, the primitive assembly 1208 stage may be configured to group every three consecutive vertices as a geometric primitive (e.g., a triangle) for transmission to the geometry shading 1210 stage. In some embodiments, specific vertices may be reused for consecutive geometric primitives (e.g., two consecutive triangles in a triangle strip may share two vertices). The primitive assembly 1208 stage transmits geometric primitives (e.g., a collection of associated vertices) to the geometry shading 1210 stage.

The geometry shading 1210 stage processes geometric primitives by performing a set of operations (e.g., a geometry shader or program) on the geometric primitives. Tessellation operations may generate one or more geometric primitives from each geometric primitive. In other words, the geometry shading 1210 stage may subdivide each geometric primitive into a finer mesh of two or more geometric primitives for processing by the rest of the graphics processing pipeline. The geometry shading 1210 stage transmits geometric primitives to the viewport SCC 1212 stage.

In an embodiment, the graphics processing pipeline may operate within a streaming multiprocessor and the vertex shading 1206 stage, the primitive assembly 1208 stage, the geometry shading 1210 stage, the fragment shading 1216 stage, and/or hardware/software associated therewith, may sequentially perform processing operations. Once the sequential processing operations are complete, in an embodiment, the viewport SCC 1212 stage may utilize the data. In an embodiment, primitive data processed by one or more of the stages in the graphics processing pipeline may be written to a cache (e.g. L1 cache, a vertex cache, etc.). In this case, in an embodiment, the viewport SCC 1212 stage may access the data in the cache. In an embodiment, the viewport SCC 1212 stage and the rasterization 1214 stage are implemented as fixed function circuitry.

The viewport SCC 1212 stage performs viewport scaling, culling, and clipping of the geometric primitives. Each surface being rendered to is associated with an abstract camera position. The camera position represents a location of a viewer looking at the scene and defines a viewing frustum that encloses the objects of the scene. The viewing frustum may include a viewing plane, a rear plane, and four clipping planes. Any geometric primitive entirely outside of the viewing frustum may be culled (e.g., discarded) because the geometric primitive will not contribute to the final rendered scene. Any geometric primitive that is partially inside the viewing frustum and partially outside the viewing frustum may be clipped (e.g., transformed into a new geometric primitive that is enclosed within the viewing frustum. Furthermore, geometric primitives may each be scaled based on a depth of the viewing frustum. All potentially visible geometric primitives are then transmitted to the rasterization 1214 stage.

The rasterization 1214 stage converts the 3D geometric primitives into 2D fragments (e.g. capable of being utilized for display, etc.). The rasterization 1214 stage may be configured to utilize the vertices of the geometric primitives to setup a set of plane equations from which various attributes can be interpolated. The rasterization 1214 stage may also compute a coverage mask for a plurality of pixels that indicates whether one or more sample locations for the pixel intercept the geometric primitive. In an embodiment, z-testing may also be performed to determine if the geometric primitive is occluded by other geometric primitives that have already been rasterized. The rasterization 1214 stage generates fragment data (e.g., interpolated vertex attributes associated with a particular sample location for each covered pixel) that are transmitted to the fragment shading 1216 stage.

The fragment shading 1216 stage processes fragment data by performing a set of operations (e.g., a fragment shader or a program) on each of the fragments. The fragment shading 1216 stage may generate pixel data (e.g., color values) for the fragment such as by performing lighting operations or sampling texture maps using interpolated texture coordinates for the fragment. The fragment shading 1216 stage generates pixel data that is transmitted to the raster operations 1218 stage.

The raster operations 1218 stage may perform various operations on the pixel data such as performing alpha tests, stencil tests, and blending the pixel data with other pixel data corresponding to other fragments associated with the pixel. When the raster operations 1218 stage has finished processing the pixel data (e.g., the output data 1202), the pixel data may be written to a render target such as a frame buffer, a color buffer, or the like.

It will be appreciated that one or more additional stages may be included in the graphics processing pipeline in addition to or in lieu of one or more of the stages described above. Various implementations of the abstract graphics processing pipeline may implement different stages. Furthermore, one or more of the stages described above may be excluded from the graphics processing pipeline in some embodiments (such as the geometry shading 1210 stage). Other types of graphics processing pipelines are contemplated as being within the scope of the present disclosure. Furthermore, any of the stages of the graphics processing pipeline may be implemented by one or more dedicated hardware units within a graphics processor such as parallel processing unit 602. Other stages of the graphics processing pipeline may be implemented by programmable hardware units such as the streaming multiprocessor 718 of the parallel processing unit 602.

The graphics processing pipeline may be implemented via an application executed by a host processor, such as a CPU. In an embodiment, a device driver may implement an application programming interface (API) that defines various functions that can be utilized by an application in order to generate graphical data for display. The device driver is a software program that includes a plurality of instructions that control the operation of the parallel processing unit 602. The API provides an abstraction for a programmer that lets a programmer utilize specialized graphics hardware, such as the parallel processing unit 602, to generate the graphical data without requiring the programmer to utilize the specific instruction set for the parallel processing unit 602. The application may include an API call that is routed to the device driver for the parallel processing unit 602. The device driver interprets the API call and performs various operations to respond to the API call. In some instances, the device driver may perform operations by executing instructions on the CPU. In other instances, the device driver may perform operations, at least in part, by launching operations on the parallel processing unit 602 utilizing an input/output interface between the CPU and the parallel processing unit 602. In an embodiment, the device driver is configured to implement the graphics processing pipeline utilizing the hardware of the parallel processing unit 602.

Various programs may be executed within the parallel processing unit 602 in order to implement the various stages of the graphics processing pipeline. For example, the device driver may launch a kernel on the parallel processing unit 602 to perform the vertex shading 1206 stage on one streaming multiprocessor 718 (or multiple streaming multiprocessor 718 modules). The device driver (or the initial kernel executed by the parallel processing unit 602) may also launch other kernels on the parallel processing unit 602 to perform other stages of the graphics processing pipeline, such as the geometry shading 1210 stage and the fragment shading 1216 stage. In addition, some of the stages of the graphics processing pipeline may be implemented on fixed unit hardware such as a rasterizer or a data assembler implemented within the parallel processing unit 602. It will be appreciated that results from one kernel may be processed by one or more intervening fixed function hardware units before being processed by a subsequent kernel on a streaming multiprocessor 718.

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the disclosure as claimed. The scope of inventive subject matter is not limited to the depicted embodiments but is rather set forth in the following Claims.

What is claimed is:

1. A lithograph mask generation process comprising:
applying optical lithography simulation on a mask image to generate a resist image;
performing curvilinear design retargeting on the resist image;
determining a gradient from the generated resist image and a configured target resist image; and
applying the gradient to update the mask image.

2. The lithograph mask generation process of claim 1, wherein the gradient is based on edge placement error.

3. The lithograph mask generation process of claim 1, wherein the gradient is based on a process variation band.

4. The lithograph mask generation process of claim 3, wherein determination of the process variation band is based at least in part on a minimum shape distance in the mask image.

5. The lithograph mask generation process of claim 3, wherein determination of the process variation band is based at least in part on a minimum shape area in the mask image.

6. The lithograph mask generation process of claim 1, wherein the gradient is based on a Fourier transform of the mask image.

7. The lithograph mask generation process of claim 1, further comprising:
transforming the mask image with differentiable morphological operators.

8. The lithograph mask generation process of claim 7, wherein the morphological operators comprise an opening operator.

9. The lithograph mask generation process of claim 7, wherein the morphological operators comprise a closing operator.

10. The lithograph mask generation process of claim 7, wherein the morphological operators are configured to comply with curvilinear mask rules.

11. The lithograph mask generation process of claim 7, wherein the morphological operators comprise a structuring element.

12. The lithograph mask generation process of claim 11, wherein the structuring element is a disk.

13. A system comprising:
at least one data processor;
a non-volatile machine-readable medium comprising instructions that, when applied to the at least on data processor, configure the system to:
perform curvilinear design retargeting on a lithographic resist image for a circuit;
determine a gradient from the resist image and a configured target resist image for the circuit; and
apply the gradient to update a lithographic mask image for the circuit.

14. The system of claim 13, wherein the gradient is based on edge placement error.

15. The system of claim 13, wherein the gradient is based on a process variation band.

16. The system of claim 15, wherein determination of the process variation band is based at least in part on a minimum shape distance in the mask image.

17. The system of claim 15, wherein determination of the process variation band is based at least in part on a minimum shape area in the mask image.

18. The system of claim 13, wherein the instructions, when applied to the at least on data processor, further configure the system to:
transform the mask image with differentiable morphological operators.

19. The system of claim 18, wherein the morphological operators comprise an opening operator.

20. The system of claim 18, wherein the morphological operators comprise a closing operator.

21. The system of claim 18, wherein the morphological operators are configured to comply with curvilinear mask rules.

22. The system of claim 18, wherein the morphological operators comprise a structuring element.

23. The system of claim 22, wherein the structuring element is a disk.

24. A non-volatile machine-readable medium comprising instructions that, when applied to at least on data processor, configure the at least one data processor to:
perform curvilinear design retargeting on a lithographic resist image for a circuit;
determine a gradient from the resist image and a configured target resist image for the circuit; and
apply the gradient to update a lithographic mask image for the circuit.
